(19) United States
(12) Patent Application Publication
(10) Pub. No.: US 2025/0311562 A1
(43) Pub. Date: Oct. 2, 2025

(54) TRANSISTOR AND DISPLAY DEVICE INCLUDING THE SAME

(71) Applicant: LG Display Co., Ltd., Seoul (KR)

(72) Inventors: Dae Hwan KIM, Paju-si (KR); Ki Tae KIM, Paju-si (KR); Min Gu KANG, Paju-si (KR); Seo Yeon IM, Paju-si (KR); Do Hun KWAK, Paju-si (KR)

(73) Assignee: LG Display Co., Ltd., Seoul (KR)

(21) Appl. No.: 19/065,274

(22) Filed: Feb. 27, 2025

(30) Foreign Application Priority Data
Mar. 27, 2024 (KR) 10-2024-0041816

(51) Int. Cl. H10K 59/124; H10D 30/67

(52) U.S. Cl. CPC H10K 59/124; H10D 30/6736

(57) ABSTRACT

Disclosed is a transistor including an active layer disposed on a substrate, the active layer including an oxide semiconductor material having a first metal, a gate insulating film disposed on the active layer, a gate electrode at least partially overlapping the active layer on the gate insulating film, a first source-drain electrode and a second source-drain electrode respectively connected to a first source-drain region and a second source-drain region of the active layer, while being insulated from the gate electrode, and a second metal oxide insulating film doped with the first metal, the second metal oxide insulating film being disposed between the gate insulating film and the active layer.

### CROSS-REFERENCE TO RELATED APPLICATION(S)

This application claims the benefit of Korean Patent Application No. 10-2024-0041816, filed on Mar. 27, 2024, which is hereby incorporated by reference as if fully set forth herein.

### BACKGROUND

### Technical Field

The present disclosure relates to a transistor and a display device including the same, and more specifically, to a transistor to improve reliability and a display device including the same.

### Description of the Related Art

Display devices for displaying images in TVs, monitors, mobile phones, tablet computers, and laptops are used in various modes and configurations.

Display devices include a display panel having a plurality of light emitting elements or liquid crystals for displaying an image, and transistors for controlling the operation of each light emitting element or liquid crystal, to display an image to be displayed through the light emitting elements or liquid crystals.

A display device is provided with a plurality of driving and switching elements to drive and control a plurality of pixels. The driving and switching elements may include transistors and the transistors are widely applied to integrated circuits as well as to pixels.

### BRIEF SUMMARY

Various research and development efforts have been conducted to by the inventors of the present disclosure to improve the performance and reliability of transistors. Accordingly, various embodiments of the disclosure are directed to a transistor and a display device including the same that substantially obviate one or more problems due to the limitations and disadvantages of the related art.

Various embodiments of the present disclosure provide a transistor to maintain uniform brightness and a display device including the same.

Various embodiments of the present disclosure provide a transistor to maintain a uniform on-state current level, prevent an increase in the level of an off-state current, reduce the occurrence of leakage current, and provide high-speed operation, and a display device including the same.

Various embodiments of the present disclosure provide a transistor to increase the threshold voltage and reduce the size of the transistor, and a display device including the same.

Various embodiments of the present disclosure provide a transistor to improve operation stability and reliability, and a display device including the same.

Various embodiments of the present disclosure provide a transistor to reduce the defect rate of display devices, reduce greenhouse gases generated by the manufacturing process, and to realize ESG (environmental/social/governance) goals, and a display device including the same.

Additional advantages, technical benefits, and features of the disclosure will be set forth in part in the description which follows and in part will become apparent to those having ordinary skill in the art upon examination of the following, or may be learned from practice of the disclosure. These and other advantages of the disclosure may be realized and attained by the structure particularly pointed out in the written description and claims hereof as well as the appended drawings.

A transistor according to one embodiment of the present disclosure includes an active layer disposed on a substrate, the active layer including an oxide semiconductor material having a first metal, a gate insulating film disposed on the active layer, a gate electrode at least partially overlapping the active layer on the gate insulating film, a first source-drain electrode and a second source-drain electrode respectively connected to a first source-drain region and a second source-drain region of the active layer, while being insulated from the gate electrode, and a second metal oxide insulating film doped with the first metal, the second metal oxide insulating film being disposed between the gate insulating film and the active layer.

The second metal oxide insulating film doped with the first metal may be an additional gate insulating film.

The additional gate insulating film may include Ga, Ga—O bonding, a second metal, a second metal-O bonding, and a Ga-second metal bonding.

The second metal oxide insulating film doped with the first metal may include a unbonded first metal, a first metal-O bonding, a unbonded second metal, a second metal-O bonding, and a first metal-second metal bonding.

In a modified embodiment, a density of the first metal in the second metal oxide insulating film doped with the first metal may increase with a decreasing distance from the active layer.

The density of the second metal or the density of the second metal-O bonding in the second metal oxide insulating film doped with the first metal may increase with a decreasing distance from the gate insulating film.

The density of the first metal-O bonding in the second metal oxide insulating film doped with the first metal may increase with a decreasing distance from the active layer.

The second metal oxide insulating film doped with the first metal may be in contact with the lower surface of the gate insulating film and may be in contact with the upper surface of the active layer.

The first metal may be Ga.

The second metal may include one of group 3 (Sc, Y), group 4 (Ti, Zr, Hf), and group 5 (V, Nb, Ta).

The second metal oxide insulating film doped with the first metal may be disposed in a pattern corresponding to an area where the gate electrode and the active layer overlap.

The second metal oxide insulating film doped with the first metal may be disposed in an area where the channel region of the active layer overlaps, and the gate insulating film may be disposed in an area where the entire area of the active layer overlaps.

The second metal oxide insulating film doped with the first metal may include a first additional gate insulating film disposed on the active layer, a second additional gate insulating film disposed on the first additional gate insulating film, and a third additional gate insulating film disposed on the second additional gate insulating film, wherein the first additional gate insulating film is in contact with an upper surface of the active layer, and the third additional gate insulating film is in contact with a lower surface of the gate insulating film.

A display device according to one embodiment of the present disclosure includes a substrate, a transistor including an active layer disposed on a substrate, the active layer including an oxide semiconductor material having a first metal, a gate insulating film disposed on the active layer, a gate electrode at least partially overlapping the active layer on the gate insulating film, a first source-drain electrode and a second source-drain electrode respectively connected to a first source-drain region and a second source-drain region of the active layer, while being insulated from the gate electrode, and a second metal oxide insulating film doped with the first metal, the second metal oxide insulating film being disposed between the gate insulating film and the active layer, a planarization film disposed on the transistor, a light emitting element disposed on the planarization film, and an encapsulation layer disposed on the light emitting element.

The transistor may be a driving transistor.

It is to be understood that both the foregoing general description and the following detailed description of the disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a plan view illustrating a display device according to one embodiment;

FIG. 2 is a circuit diagram illustrating a sub-pixel according to one embodiment;

FIG. 3 is a cross-sectional view illustrating a transistor according to one embodiment;

FIG. 4 illustrates a modified embodiment of a second metal oxide insulating film doped with a first metal shown in FIG. 3;

FIG. 5 is a cross-sectional view illustrating a transistor according to another embodiment;

FIG. 6 is a cross-sectional view illustrating a transistor according to another embodiment; and

FIG. 7 is a cross-sectional view illustrating a display device including the transistor according to one embodiment.

### DETAILED DESCRIPTION

Hereinafter, embodiments will be described with reference to the drawings.

Like reference numbers refer to like components throughout the description of the figures. The thickness, ratio, size, and the like of components shown in the drawings to illustrate various embodiments of the present disclosure are exaggerated for better illustration. The scale of the components shown in the drawings is different from the actual scale for better illustration and is therefore not limited to the scale shown in the drawings.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

It will be understood that, when an element (or a region, layer, film or part) is referred to as being “on”, “connected to” or “bound to” another element, it may be directly on, connected to or bound to the other element, or an intervening element may also be present therebetween.

The expression “and/or” includes all of one or more combinations that may be defined by the associated components.

The text “at least one of A or B” as used herein should be understood to include at least one of A, or at least one of B, or at least one of both A and B. This similarly applies to “at least one of A, B, or C” and so forth.

In describing the variety of embodiments of the present disclosure, terms such as “first” and “second” may be used to describe a variety of components, but these terms only aim to distinguish the same or similar components from one another. Accordingly, throughout the disclosure, a “first” component may be referred to as a “second” component within the technical concept of the present disclosure. Similarly, a “second” component may be referred to as a “first” component within the technical concept of the present disclosure. Singular forms are intended to include plural forms as well, unless the context clearly indicates otherwise.

Spatially relative terms, such as “below”, “beneath”, “above”, and “upper”, may be used herein to describe the relationship between elements as shown in the figures. It will be understood that these terms are spatially relative and thus described based on the orientation depicted in the figures. For example, at least one intervening element may be present between the two elements, unless “immediately” or “directly” is used. Spatially relative terms, such as “below”, “beneath”, “above”, and “upper”, may be used herein to easily describe the correlation between one element or component and other elements or components. It will be understood that spatially relative terms are intended to encompass different orientations of a device during the use or operation of the device, in addition to the orientation depicted in the figures. For example, if a device in one of the figures is turned upside down, elements described as “below” or “beneath” other elements would then be positioned “above” the other elements. The exemplary term “below” or “beneath” can, therefore, encompass the meanings of both “below” and “above”.

It will be further understood that the terms “comprises” and/or “has”, when used in this specification, specify the presence of stated features, integers, steps, operations, elements, parts or combinations thereof, but do not preclude the presence or addition of one or more other features, integers, steps, operations, elements, parts, or combinations thereof.

Features of various embodiments of the present disclosure may be partially or completely integrated or combined with each other, and may be variously interoperated with each other and driven technically. The embodiments of the present disclosure may be carried out independently from each other, or may be carried out together in an interrelated manner.

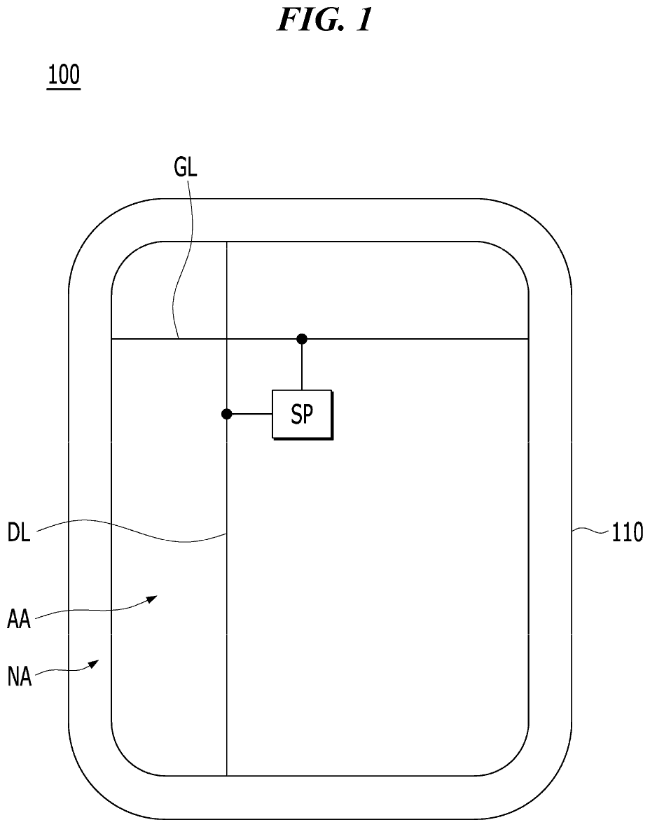

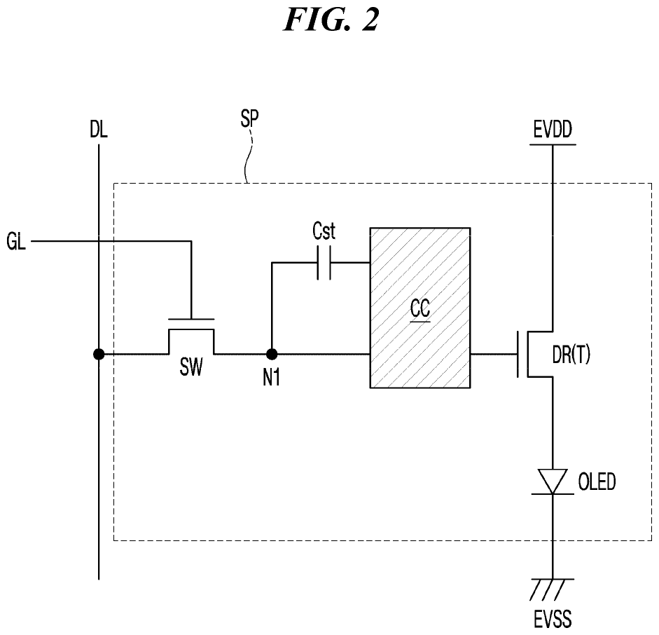

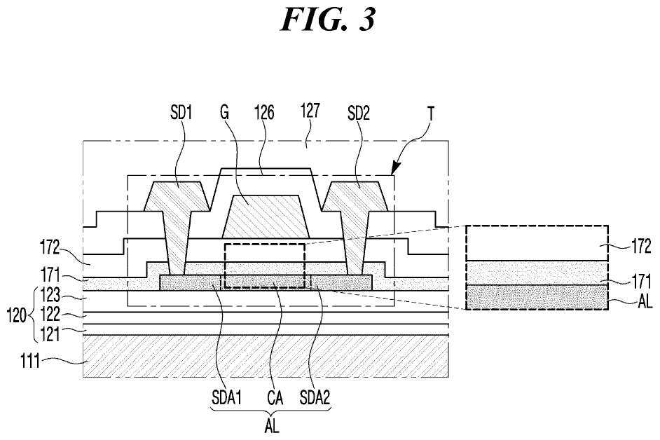

Hereinafter, a preferred example of a display device according to an embodiment of the present disclosure will be described in detail with reference to the attached drawings. FIG. 1 is a plan view illustrating a display device according to one embodiment, FIG. 2 is a circuit diagram illustrating a sub-pixel according to one embodiment, and FIG. 3 is a cross-sectional view illustrating a transistor according to one embodiment.

Referring to FIGS. 1 and 2, the display device 100 according to an example of the present disclosure includes a display panel 110 and may be divided into a display area AA and a non-display area NA.

The display area AA is an area that displays an image. A plurality of sub-pixels SP is disposed in the display area AA of the display panel 110, and an image may be displayed using the plurality of sub-pixels SP. The area where the plurality of sub-pixels SP is arranged may be the display area AA, and the area other than the display area AA may be the non-display area NA.

The non-display area NA may be disposed in an edge area surrounding the display area AA that displays the image. At least one driver for driving a plurality of sub-pixels SP may be disposed in the non-display area NA. The driver may be a gate-in-panel (GIP).

Various additional elements may be further disposed in the non-display area NA to drive the sub-pixels SP in the display area AA.

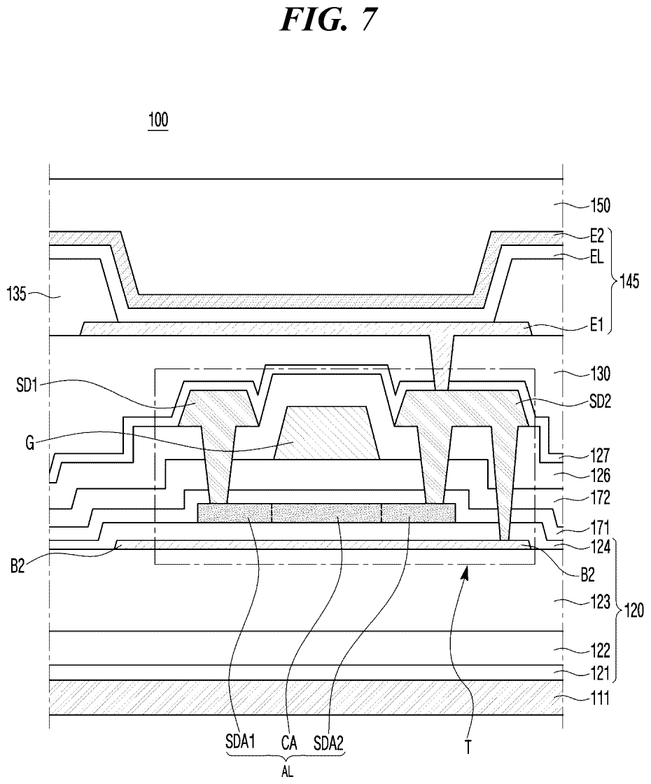

Among the pixels, at least one sub-pixel SP includes a first transistor SW, a second transistor DR (T), a capacitor Cst, a compensation circuit CC, and a light emitting element (OLED, organic light emitting diode, 145, see FIG. 7), as shown in FIG. 2.

For example, the first transistor SW may be a switching transistor and the second transistor DR (T) may be a driving transistor.

The first electrode (e.g., drain electrode) of the first transistor SW is electrically connected to the data line DL, and the second electrode (e.g., source electrode) is electrically connected to the first node N1. The gate electrode of the first transistor SW is electrically connected to the gate line GL. The first transistor SW transmits the data signal supplied through the data line DL to the first node N1 in response to the scan signal supplied through the gate line GL.

The capacitor Cst is electrically connected to the first node N1 and charges the voltage applied to the first node N1.

The first electrode (e.g., drain electrode) of the second transistor DR receives a high potential driving voltage (EVDD), and the second electrode (e.g., source electrode) is electrically connected to a first electrode (e.g., a first electrode E1 as an anode, see FIG. 7) of the light emitting element (OLED). A second electrode (e.g. a second electrode E2 as a cathode, see FIG. 7) of the light emitting element (OLED) may be connected to a low potential voltage (EVSS). The second transistor DR (T) may control the amount of driving current flowing through the light emitting element (OLED) in response to the voltage applied to the gate electrode.

The active layer of the first transistor SW and/or the second transistor DR (T) may contain silicon such as amorphous silicon (a-Si), polycrystalline silicon (poly-Si), or low-temperature polycrystalline silicon (poly-Si), or may contain an oxide semiconductor material such as IGZO (indium-gallium-zinc-oxide).

The first transistor (SW) or the second transistor (DR) according to an embodiment of the present disclosure includes an oxide semiconductor material, and the detailed description of the transistor including an oxide semiconductor material is given below with reference to FIG. 3.

Meanwhile, the light emitting element (OLED) shown in FIG. 2 outputs light corresponding to the driving current. The light emitting element (OLED) may output any one of red, green, blue, and white light.

The light emitting element (OLED) may include an anode, a light emitting layer disposed on the anode, and a cathode supplying a common voltage. The light emitting layer may be implemented to emit light of the same color for each pixel, such as white light, or may be implemented to emit different colors for each sub-pixel SP, such as red, green, or blue light.

The light emitting element (OLED) may be a front-emitting diode or a back-emitting diode.

The compensation circuit CC may be provided in the sub-pixel SP to compensate for the threshold voltage of the second transistor DR. The compensation circuit CC may include one or more transistors. The compensation circuit CC may include at least one transistor and capacitor, and may be configured in various configurations depending on the compensation method. The pixel including the compensation circuit CC may have various structures such as 3T1C, 4T2C, 5T2C, 6T1C, 6T2C, 7T1C, and 7T2C.

Referring to FIG. 3, the transistor T according to an embodiment of the present disclosure will be described. The transistor T of the embodiments described below may be applied to the second transistor DR (T) that functions as a driving transistor of FIG. 2.

The transistor T according to one embodiment of the present disclosure includes, on a substrate 111, an active layer AL including an oxide semiconductor material having a first metal, a second metal oxide insulating film 171 doped with the first metal, a gate insulating film 172, a gate electrode G overlapping a channel area CA of the active layer AL, and a first source-drain electrode SD1 and a second source-drain electrode SD2 connected to first and second source-drain regions SDA1 and SDA2 of the active layer AL.

The transistor T is disposed on the substrate 111, and the substrate 111 serves to support and protect components of the transistor T and components of the display device 100 disposed thereon.

The substrate 111 is formed of a flexible plastic material and is thus flexible. The substrate 111 may be formed of polyimide and may contain a flexible and thin glass material.

The substrate 111 may independently include a support substrate such as PET (polyethylene terephthalate) and a polyimide film. The substrate 111 may include an adhesive film such as a pressure sensitive adhesive (PSA) film to adhere the PET to the polyimide film. The substrate 111 may have a structure in which two layers are stacked via an intermediate layer (not shown) as an insulating film such as silicon nitride or silicon oxide, interposed therebetween.

A plurality of stacked insulating films 120 is disposed on the display area AA and the non-display area NA of the substrate 111 to insulate the electrodes constituting the transistor T from each other. The insulating film 120 includes a first insulating film 121, a second insulating film 122, and a third insulating film 123. The insulating film 120 may further include a fourth insulating film 124, a sixth insulating film 126, and a seventh insulating film 127 shown in FIG. 7.

The first insulating film 121 may be disposed in the display area AA and the non-display area NA on the substrate 111. The first insulating film 121 may be called a “buffer film” and may have the same function as the buffer film known in the technical field. The first insulating film 121 is disposed on the substrate 111 to protect structures on the substrate 111 that are vulnerable to moisture permeation from moisture penetrating through the substrate 111 and to planarize the surface of the substrate 111.

The first insulating film 121 may be a single inorganic film or may include a plurality of alternately-stacked inorganic films.

For example, the first insulating film 121 may include at least one inorganic film selected from the group consisting of a silicon oxide (SiOx) film, a silicon nitride (SiNx) film, and a silicon oxynitride (SiOxNy) film, or may include a multilayer film in which the inorganic films described above are stacked.

The second insulating film 122 may be disposed on the first insulating film. The second insulating film 122 may function as a second buffer layer and may also function as a gate insulating film for other kinds of transistors (not shown) constituting the gate driver (not shown) disposed in the non-display area NA.

The second insulating film 122 may include an inorganic film, for example, a silicon oxide film (SiOx), or a silicon nitride film (SiNx), or a multilayer film thereof.

The third insulating film 123 may be disposed on the second insulating film 122. The third insulating film 123 may function as an interlayer insulating film for other kinds of transistors (not shown) constituting the gate driver (not shown) disposed in the non-display area NA.

The third insulating film 123 may contain an inorganic material. The inorganic material may include, for example, silicon nitride (SiOx) or the third insulating film 123 may include a multilayer film in which inorganic films are stacked.

When the third insulating film 123 includes a silicon oxide film, hydrogen particles are not discharged during heat treatment, or the like, during the process, to prevent reduction in reliability of the active layer AL containing an oxide semiconductor material adjacent to the third insulating film 123 due to hydrogen particles.

In particular, the driving transistor directly contributes to the operation of the light emitting element and it is important for the driving transistor to secure reliability. For this purpose, the structure for securing the reliability of the transistor according to embodiments of the present disclosure will be further described in detail later.

The active layer AL may be disposed on the third insulating film 123.

The active layer AL includes a channel area CA overlapping the gate electrode G, and first and second source drain regions SDA1 and SDA2 respectively connected to the first and second source drain electrodes SD1 and SD2.

The channel area CA is an area that overlaps the gate electrode G and through which carriers move. The channel area CA may not be doped with impurities.

The first source drain area SDA1 and the second source drain area SDA2 are areas excluding the channel area CA, and are respectively connected to the first source drain electrode SD1 and the second source drain electrode SD2 to inject electrons and holes. The first source drain area SDA1 and the second source drain area SDA2 may be disposed on both sides of the channel area CA with the channel area CA interposed therebetween.

The first source drain area SDA1 and the second source drain area SDA2 include a conductive portion doped with impurities, and the like. The first source drain area SDA1 and the second source drain area SDA2 may include a mixed area of a conductive area doped with impurities and a non-conducting area not doped with impurities.

The active layer AL contains an oxide semiconductor material including a first metal. The oxide semiconductor material is an oxide of a first metal of zinc (Zn), indium (In), gallium (Ga), tin (Sn), or titanium (Ti), or a combination of a first metal of zinc (Zn), indium (In), gallium (Ga), tin (Sn), or titanium (Ti), and an oxide thereof.

More specifically, the oxide semiconductor material including a first metal constituting the active layer AL may include at least one of an IGZO (InGaZnO), IGO (InGaO), IGZTO (InGaZnSnO), GZTO (GaZnSnO), GZO (GaZnO), or GO (GaO)-based oxide semiconductor material. The active layer AL may have a single-film structure or a multilayer film structure including two or more oxide semiconductor materials.

The active layer AL is disposed on a substrate 111 and the active layer AL includes an oxide semiconductor material having a first metal, so that the transistor improves the effect of blocking leakage current and thus reduces power consumption.

The gate insulating film 172 may be disposed on the active layer AL. Since the active layer AL is disposed on the third insulating film 123 in a pattern shape, the gate insulating film 172 is disposed to cover the upper and side surfaces of the active layer AL.

Since the gate insulating film 172 is disposed to cover the active layer AL containing an oxide semiconductor material, it may be formed of an inorganic material containing no hydrogen particles. For example, the gate insulating film 172 may include a silicon oxide layer (SiOx) or multiple layers in which inorganic layers are stacked.

The gate electrode G may be disposed on the gate insulating film 172. The gate electrode G function to turn on or turn off the second transistor DR (T) in response to a signal from the compensation circuit CC or the capacitor Cst shown in FIG. 2. The gate electrode G is insulated from the active layer AL through the gate insulating film 172, and is arranged such that at least a part of the gate electrode G overlaps the active layer AL to form a channel area CA in the active layer AL.

The gate electrode G may contain a conductive metal material. Specifically, the conductive metal material includes at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), or titanium (Ti). The gate electrode G may have a multilayer structure including at least two conductive metal materials.

When current is applied to the gate electrode G, charges flow into the channel area CA of the active layer AL overlapping the gate electrode G. The transistor T according to the present disclosure has a second metal oxide insulating film 171 doped with the first metal of the active layer AL at the interface between the active layer AL and the gate insulating film 172 so as to allow charges to smoothly flow into the channel area CA of the active layer AL without being trapped.

The second metal oxide insulating film 171 doped with the first metal is disposed to cover the active layer AL so as to overlap with the channel area CA of the active layer AL at the interface between the active layer AL and the gate insulating film 172. The second metal oxide insulating film 171 doped with the first metal covers the entire upper surface of the active layer AL and contacts the upper surface and side surfaces of the active layer AL.

The second metal oxide insulating film 171 doped with the first metal may contact at least a part of the third insulating film 123 disposed below the active layer AL. The second metal oxide insulating film 171 doped with the first metal may contact the lower surface of the gate insulating film 172 and may contact the upper surface of the active layer AL.

The second metal oxide insulating film 171 doped with the first metal includes the first metal included in the oxide semiconductor material of the active layer AL in common. The second metal oxide insulating film 171 doped with the first metal may include the first metal, a first metal-O (oxide) bonding, a second metal, a second metal-O bonding, and a first metal-second metal bonding. The first metal and the second metal may be partially unbonded within the second metal oxide insulating film 171.

Specifically, the first metal may be a metal common to the first metal of the active layer AL and may be Ga (gallium). When the second metal oxide insulating film 171 doped with the first metal functions as an additional gate insulating film, the additional gate insulating film may include Ga, Ga—O bonding, a second metal, a second metal-O bonding, and a Ga-second metal bonding. The second metal may be different from the first metal. When the first metal is Ga, the second metal may be a metal other than Ga.

The second metal of the second metal oxide insulating film 171 doped with the first metal may include one of group 3 (Sc, Y), group 4 (Ti, Zr, Hf), and group 5 (V, Nb, Ta) metals. When the first metal is Ga, the first metal-second metal bonding in the second metal oxide insulating film 171 may include, for example, any one of Ga—Ta, Ga—Zr, and Ga—Y.

When the surface of the channel area CA of the active layer AL comes into contact with the gate insulating film 172, the structure or properties of the gate insulating film 172 may be different from those of the active layer AL with which it comes into contact, and thus charges of the active layer AL may be trapped at the interface between the active layer AL and the gate insulating film 172 or at the lower surface of the gate insulating film 172. When the charge does not flow but is trapped between the active layer AL and the gate insulating film 172, it may affect the concentration or mobility of the charges, which may reduce the electrical stability of the transistor.

The transistor T according to one embodiment of the present disclosure includes a second metal oxide insulating film 171 doped with a first metal at the interface between the active layer AL and the gate insulating film 172. The second metal oxide insulating film 171 is doped with a first metal identical to the first metal of the active layer AL and thus has a bonding structure similar to the internal bonding structure of the active layer AL having the first metal.

In addition, the second metal oxide insulating film 171 includes oxygen (oxide; O) and thus has a bonding structure in the form of an oxide insulating film, while also including the second metal and additionally having a bonding structure with the second metal. The second metal oxide insulating film 171 has bonding between the first metal and oxygen, bonding between the second metal and oxygen, and bonding between the first metal and the second metal, so that the portion of the bonding structure in the second metal oxide insulating film 171 exists and the area where charges are trapped is reduced. Therefore, the second metal oxide insulating film 171 has a structure similar to the gate insulating film 172, and at the same time, the portion where charges may be trapped is reduced compared to the gate insulating film 172.

The second metal oxide insulating film 171 doped with the first metal has a structure and properties similar to the structures and properties of the lower active layer AL and the upper gate insulating film 172 at the interface between the active layer AL and the gate insulating film 172, so that charges flowing to the active layer AL or the surface of the active layer AL can flow smoothly without being trapped. In addition, the second metal oxide insulating film 171 doped with the first metal has a lower interface trap density than the upper gate insulating film 172 at the interface with the active layer AL, so that charges flow smoothly without getting trapped and remaining at the interface between the active layer AL and the second metal oxide insulating film 171 but, thereby inhibiting the occurrence of afterimages, and the like. The second metal oxide insulating film 171 is disposed to directly contact the active layer AL.

According to one embodiment of the present disclosure, a transistor T has a second metal oxide insulating film 171 doped with a first metal placed between an active layer AL having the first metal and a gate insulating film 172, so that charges flowing through the active layer AL or the surface of the active layer AL are not trapped, the concentration and mobility of charges can be uniformly maintained, the characteristics of the transistor T can be uniformly maintained, the current supplied from the transistor T is made uniform when the transistor T is connected to a light emitting element, the brightness of the light emitting element can be uniformly maintained, and stability and reliability can be improved.

In addition, the transistor according to one embodiment of the present disclosure includes a second metal oxide insulating film 171 doped with the first metal between the active layer AL having the first metal and the gate insulating film 172 to prevent current or charges from being trapped, thereby maintaining the level of the on-current of the transistor T uniformly, preventing an increase in the level of the off-current, reducing the occurrence of leakage current and providing high-speed operation of the transistor T.

The transistor according to one embodiment of the present disclosure includes a second metal oxide insulating film 171 doped with the first metal disposed between the active layer AL having the first metal and the gate insulating film 172, so that the amount of charges trapped can be reduced compared to a general transistor, the thickness of the active layer AL can be reduced in relation to performance, the threshold voltage Vth can be increased due to the decrease in the channel thickness of the active layer AL, and the size of the transistor T can be reduced.

The second metal oxide insulating film 171 doped with the first metal is an oxide insulating film and has electrical or chemical properties as an inorganic insulating film, thus functioning as a general gate insulating film. That is, the second metal oxide insulating film 171 doped with the first metal may function as an additional gate insulating film under the gate insulating film 172.

The second metal oxide insulating film 171 doped with the first metal may further improve the stability and reliability of the transistor T by controlling the density distribution of bonding structures within the second metal oxide insulating film 171.

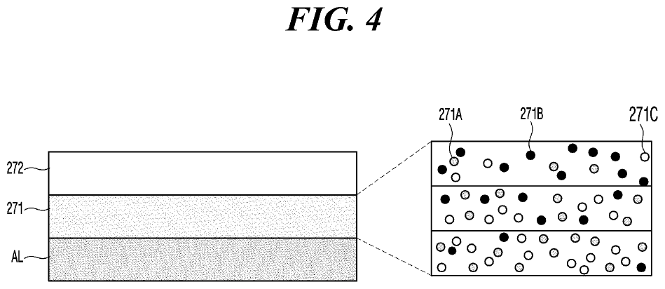

FIG. 4 illustrates a modified embodiment of the second metal oxide insulating film doped with the first metal of FIG. 3. Referring to FIG. 4, the second metal oxide insulating film 271 doped with the first metal may include a first metal 271A, a second metal bond 271B, and a first metal bond 271C. The second metal bond 271B may be a second metal or a second metal-O (oxide) bonding structure. The first metal bond 271C may have a first metal-O (oxide) bonding structure.

The density of the first metal 271A doped in the second metal oxide insulating film 271 increases with decreasing distance from the active layer AL. The density of the first metal bond 271C in the second metal oxide insulating film 271 also increases with decreasing distance from the active layer AL.

As the density of the first metal 271A and/or the density of the first metal bond 271C in the second metal oxide insulating film 271 increases with decreasing distance from the active layer AL having the first metal, the density that may be trapped at the active layer AL or the surface of the active layer AL decreases. Accordingly, the transistor T according to the modified embodiment of the present disclosure has smooth charge movement and reduced leakage current.

The density of the second metal bond 271B in the second metal oxide insulating film 271 increases with decreasing distance from the gate insulating film 272. The second metal bond 272B may be, for example, a bonding of the second metal and oxygen (second metal-O). When the density of the second metal compound 271B increases toward the gate insulating film 272 from the active layer AL, the second metal oxide insulating film 271 may increase the dielectric constant as an additional gate insulating film, thereby increasing the charge amount. Accordingly, the transistor T according to the modified embodiment of the present disclosure may realize high-speed operation according to the increase in the charge amount.

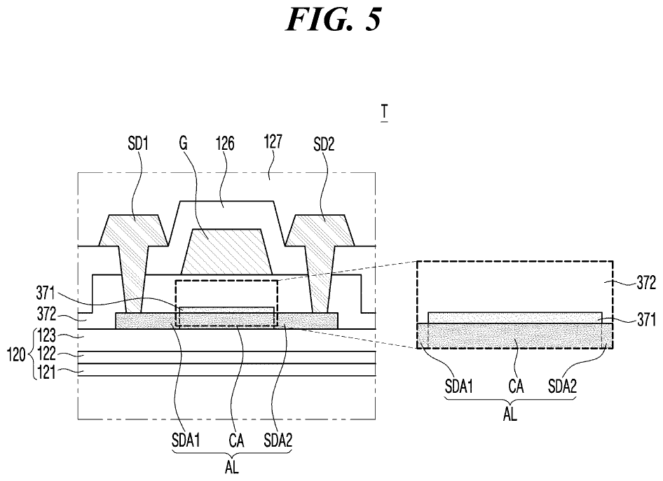

FIG. 5 is a cross-sectional view illustrating a transistor according to another embodiment and the configurations having the same reference numerals described in other drawings may be applied or implemented in the same manner as the embodiment of FIG. 5, or may be applied or implemented as embodiments linked or combined with the embodiments described with reference to other drawings. Detailed description of the configurations having the same reference numerals may be omitted.

Referring to FIG. 5, the transistor T may include electrodes disposed between insulating films 120 on a substrate 111. A second metal oxide insulating film 371 doped with a first metal may be disposed to correspond to an area overlapping the channel area CA of the active layer AL at an interface between the active layer AL and the gate insulating film 372. The second metal oxide insulating film 371 doped with the first metal may be disposed in a patterned form in an area where the gate electrode G overlaps the active layer AL.

The gate insulating film 372 may be disposed in an area overlapping the entire area of the active layer AL, and the gate insulating film 372 may be in contact with the upper surface and side surface of the second metal oxide insulating film 371 doped with the patterned first metal, and may be in contact with the upper surface of the first source-drain area SDA1 and the second source-drain area SDA2 of the active layer AL.

The second metal oxide insulating film 371 doped with the first metal according to another embodiment of the present disclosure may be disposed to have a width corresponding to the width of the gate electrode G.

The movement of charges on the surface of the active layer AL or the active layer AL and the charge trap at the interface with the gate insulating film 372 mostly occur in the area overlapping the channel area CA. Therefore, the objects according to the present disclosure can be achieved even if the second metal oxide insulating film 371 doped with the first metal is disposed in a pattern such that the second metal oxide insulating film 371 overlaps the channel area CA of the active layer AL as in other embodiments of the present disclosure.

According to another embodiment of the present disclosure, a transistor has a configuration in which a second metal oxide insulating film 371 doped with a first metal is disposed between an active layer AL having a first metal and a gate insulating film 372 in a pattern such that the second metal oxide insulating film 371 overlaps the channel area CA of the active layer AL, so that charges flowing through the channel area CA of the active layer AL or the surface of the channel area CA of the active layer AL are not trapped, the concentration and mobility of the charges are uniformly maintained, the luminance of the transistor T is uniformly maintained, stability and reliability are improved, and the occurrence of afterimages in the display device 100 is minimized. The transistor according to another embodiment of the present disclosure has a configuration in which an upper surface of the channel area CA of the active layer AL contacts the second metal oxide insulating film 371 to form an interface. The other surface of the second metal oxide insulating film 371 that is not in contact with the active layer AL may be in contact with the gate insulating film 372.

In addition, the transistor T according to another embodiment of the present disclosure includes a second metal oxide insulating film 371 doped with the first metal between the active layer AL having the first metal and the gate insulating film 372, thereby preventing current or charges from being trapped between the active layer AL and the gate insulating film 372. Accordingly, the level of the on-current of the transistor T according to another embodiment of the present disclosure can be maintained uniformly, an increase in the level of the off-current can be prevented, the occurrence of leakage current can be reduced, and high-speed operation of the transistor T can be provided.

According to another embodiment of the present disclosure, a transistor T includes a second metal oxide insulating film 371 doped with a first metal disposed between a channel area CA of an active layer AL having a first metal and a gate insulating film 372, thereby reducing the thickness of the active layer AL, increasing a threshold voltage Vth according to the decrease in the channel thickness of the active layer AL, and reducing the size of the transistor T.

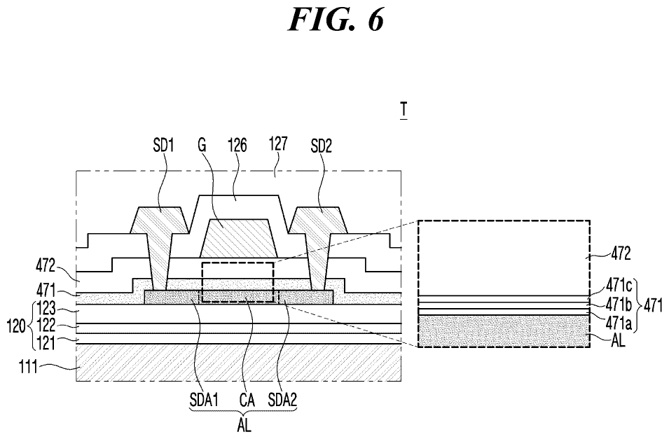

FIG. 6 is a cross-sectional view illustrating a transistor according to another embodiment, and referring to FIG. 6, the transistor T including electrodes disposed between insulating films 120 may be disposed on a substrate 111. A second metal oxide insulating film 471 doped with a first metal may be disposed between layers of the active layer AL and the gate insulating film 472 so as to correspond to an area overlapping the channel area CA of the active layer AL.

The second metal oxide insulating film 471 doped with the first metal may include a first additional gate insulating film 471a disposed on the active layer AL, a second additional gate insulating film 471b disposed on the first additional gate insulating film 471a, and a third additional gate insulating film 471c disposed on the second additional gate insulating film 47lb.

The first additional gate insulating film 471a may be disposed to contact the upper surface of the active layer AL and the third additional gate insulating film 471c may be disposed to contact the lower surface of the gate insulating film 472.

All of the first additional gate insulating film 471a, the second additional gate insulating film 47ib, and the third additional gate insulating film 471c are doped with the first metal. The density of the first metal may be different in each of the first additional gate insulating film 471a, the second additional gate insulating film 471b, and the third additional gate insulating film 471c.

The second metal is present in all of the first additional gate insulating film 471a, the second additional gate insulating film 47ib, and the third additional gate insulating film 471c, and the second metal may exist as a different metal in each layer.

For example, the second metal in the first additional gate insulating film 471a may be Ta, the second metal in the second additional gate insulating film 47lb may be Zr, and the second metal in the third additional gate insulating film 471c may be Y.

By disposing the second metal oxide insulating film 471 doped with the first metal in a structure in which multiple layers having different types of second metals are laminated, different physical properties and characteristics can be supplemented.

The first additional gate insulating film 471a, the second additional gate insulating film 471b, and the third additional gate insulating film 471c are disposed to overlap the gate electrode G or overlap the channel area CA of the active layer AL.

The transistor according to another embodiment of the present disclosure has a configuration in which a plurality of layers is laminated such that a second metal oxide insulating film 471 doped with the first metal overlaps the channel area CA of the active layer AL at the interface between the active layer AL having the first metal and the gate insulating film 472, thereby preventing the charge flowing through the active layer AL or the surface of the active layer AL from being trapped, and uniformly maintaining the concentration and mobility of the current or charge flowing to the active layer AL or the surface of the active layer AL. In addition, the concentration and mobility of the current or charge flowing to the active layer AL or the surface of the active layer AL can be prevented from decreasing, so that the brightness of the transistor T can be uniformly maintained.

In addition, the transistor T according to another embodiment of the present disclosure has a configuration in which a second metal oxide insulating film 471 doped with the first metal is disposed at the interface between the active layer AL having the first metal and the gate insulating film 472, thereby preventing current or charges from being trapped, maintaining the level of the on-current of the transistor T uniformly, preventing an increase in the level of the off-current, reducing the occurrence of leakage current and providing high-speed operation of the transistor T. Furthermore, when the second metal oxide insulating film 471 doped with the first metal is disposed at the interface between the active layer AL and the gate insulating film 472 as in another embodiment of the present disclosure, the thickness of the active layer AL can be reduced, the threshold voltage Vth can be increased due to the decrease in the channel thickness of the active layer AL, and the size of the transistor T can be reduced.

Referring to FIG. 3 again, a sixth insulating film 126 may be disposed on the gate electrode G. The sixth insulating film 126 covers the upper and side surfaces of the gate electrode G so that the first source-drain electrode SD1, the second source-drain electrode SD2, and the gate electrode G are insulated from each other.

The sixth insulating film 126 may be a single inorganic film or may include a plurality of stacked inorganic films. The inorganic film may include one or more inorganic materials selected from among a silicon oxide (SiOx) film, a silicon nitride (SiNx) film, and a silicon oxynitride (SiOxNy) film.

The first source-drain electrode SD1 and the second source-drain electrode SD2 may be disposed on the sixth insulating film 126. The first source-drain electrode SD1 and the second source-drain electrode SD2 may be disposed spaced apart from each other with the gate electrode G interposed therebetween. In this case, the gate electrode G, and the first and second source drain electrodes SD1 and SD2 may be arranged in different layers.

The first source drain electrode SD1 and the second source drain electrode SD2 may be formed of a conductive metal material. Specifically, the conductive metal material may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), or titanium (Ti). The first source drain electrode SD1 and the second source drain electrode SD2 may also have a multilayer film structure including at least two conductive metal materials.

The first source drain electrode SD1 and the second source drain electrode SD2 are each connected to the active layer AL. The first source drain electrode SD1 is connected to the first source drain region SDA1 of the active layer AL and the second source drain electrode SD2 is connected to the second source drain region SDA2 of the active layer AL. For example, the first source drain electrode SD1 and the second source drain electrode SD2 may each be connected to the active layer AL through a contact hole such as a sixth insulating film 126.

A seventh insulating film 127 may be disposed on the first source drain electrode SD1 and the second source drain electrode SD2. The seventh insulating film 127 may be disposed to flatten the upper portion of the transistor T including a pattern such as an active layer AL or a gate electrode G, a first source-drain electrode SD1, and a second source-drain electrode SD2.

The seventh insulating film 127 may be formed as an inorganic film or an organic film. The seventh insulating film 127 may have a structure in which a plurality of inorganic films are laminated or a structure in which a plurality of organic films are laminated.

By disposing a second metal oxide insulating film 171 doped with a first metal according to the present disclosure between an active layer AL and a gate insulating film 172, a second metal oxide film 171 having excellent current flow properties is disposed at the interface with the active layer AL, so that charge flow into the transistor T and the device characteristics of the transistor T can be improved.

The transistor T according to the embodiments of the present disclosure prevents current or charge flowing to the active layer AL or the surface of the active layer AL from being trapped by disposing a second metal oxide insulating film 171, 271, 371, or 471 doped with a first metal at the interface between the active layer AL having a first metal and the gate insulating film 172, 272, 372 or 472, thereby uniformly maintaining the concentration and mobility of current or charge flowing to the active layer AL or the surface of the active layer AL, and maintaining the brightness of the transistor T.

In addition, the transistor T according to the embodiments of the present disclosure prevents current or charges from being trapped by disposing a second metal oxide insulating film 171, 271, 371 or 471 doped with a first metal between layers of an active layer AL having a first metal and a gate insulating film 172, 272, 372 or 472, thereby maintaining the level of the on-current of the transistor T uniformly, preventing an increase in the level of the off-current, reducing the occurrence of leakage current, and providing high-speed operation of the transistor T.

Furthermore, when a second metal oxide insulating film 171, 271, 371, or 471 doped with a first metal is disposed between the active layer AL and the gate insulating film 172, 272, 372, or 472 as in the embodiments of the present disclosure, the thickness of the active layer AL can be reduced, the threshold voltage Vth can be increased due to the reduction in the channel thickness of the active layer AL, and the size of the transistor T applied to the display device 100 can be reduced.

That is, the threshold voltage Vth may be lowered based on the reduced size of the transistor T, but the present disclosure may increase the threshold voltage Vth by reducing the thickness of the channel area CA of the active layer AL, thereby preventing the threshold voltage Vth from being lowered, and realizing stability and reliability of the transistor T.

A display device 100 to which transistors according to embodiments of the present disclosure are applied is described with reference to FIG. 7, and configurations having the same reference numerals described with reference to FIGS. 1 to 6 may be applied or implemented in the same manner as the embodiments described with reference to FIGS. 1 to 6, or may be applied or implemented as embodiments linked or combined with the embodiments described with reference to FIGS. 1 to 6. Descriptions of configurations having the same reference numerals may be omitted.

Referring to FIG. 7, the display device 100 according to an embodiment of the present disclosure may include an insulating film 120 disposed on a substrate 111, a transistor T, a planarization layer 130 disposed on the transistor T, a light emitting element 145, and an encapsulation layer 150.

The display device 100 may further include a bank 135 that divides the light emitting element 145 into sub-pixels, and a shield layer B2 disposed between the transistor T and the substrate 111.

The insulating film 120 may include a first insulating film 121, a second insulating film 122, a third insulating film 123, a fourth insulating film 124, a sixth insulating film 126, and a seventh insulating film 127.

The shield layer B2 may be disposed between the third insulating film 123 and the fourth insulating film 124. The shield layer B2 does not necessarily have to be disposed between the third insulating film 123 and the fourth insulating film 124. When the shield layer B2 is spaced from the active layer AL, it may be disposed on any insulating film 120 under the active layer AL.

The shield layer B2 may function as a light blocking layer. The shield layer B2 may block external light incident on the active layer AL. In addition, the shield layer B2 may be a line that transmits current, power, or a signal.

The shield layer B2 may be disposed to overlap the active layer AL to prevent external light from travelling toward the active layer AL. The width or area of the shield layer B2 may be larger than the width or area of the active layer AL in order to block external light incident at an angle from the side of the active layer AL.

Specifically, the shield layer B2 of the transistor T may be arranged to overlap the channel area CA and the first/second source drain regions SDA1 and SDA2 of the active layer AL. The shield layer B2 may partially overlap the first and second source drain regions SDA1 and SDA2 of the active layer AL when viewed in a plan view.

The shield layer B2 below the active layer AL and the gate electrode G arranged above the active layer AL increase the effect of blocking external light, and prevent the change in the active layer AL due to light or slow down the change speed, thereby minimizing the increase in the off-current level of the transistor T and reducing the occurrence of leakage current.

The shield layer B2 may be made of a conductive material, for example, a metal. The shield layer B2 may be formed of a single metal, but may be formed of two or more types of metal, or an alloy of two or more types of metal. In addition, the shield layer B2 may be disposed as a single layer or multiple layers.

The shield layer B2 may be formed as a metal layer including a titanium (Ti) material having excellent hydrogen particle capturing capability. For example, the shield layer B2 may be a titanium single layer, a multilayer of molybdenum (Mo) and titanium (Ti), or an alloy of molybdenum (Mo) and titanium (Ti). The shield layer B2 may also be another metal layer including titanium (Ti).

The shield layer B2 including titanium (Ti) according to one embodiment may capture hydrogen particles diffused within the insulating film 120 disposed between the active layer AL and the shield layer B2, thereby preventing the hydrogen particles from reaching the active layer AL.

The lower end of the second source-drain electrode SD2 of the transistor T may be connected to the active layer AL, and the lower end of the second source-drain electrode SD2 may be connected to the shield layer B2. Here, the second source drain electrode SD2 may be connected at a portion that is planarly spaced from the shield layer B2 and the active layer AL.

When the second source drain electrode SD2 is connected to the shield layer B2, the effective voltage applied to the channel area of the active layer AL is inversely proportional to the parasitic capacitance between the active layer AL and the shield layer B2, so that the effective voltage applied to the active layer AL is controlled by controlling the parasitic capacitance between the active layer AL and the shield layer B2.

In one embodiment, the shield layer B2 is adjacent to the active layer AL between the fourth insulating film 124 and the third insulating film 123 below the active layer AL, so that the parasitic capacitance between the active layer AL and the shield layer B2 may be increased, but the actual current flowing in the active layer AL may be reduced through the electrical connection between the shield layer B2 and the second source-drain electrode SD2, and the grayscale control range of the transistor T may be widened.

As a result, the transistor T according to the present disclosure may be precisely controlled even at a low grayscale and may improve the problem of screen blur that frequently occur at low grayscale.

The fourth insulating film 124 may be disposed on the third insulating film 123. The fourth insulating film 124 may function as a buffer layer. The fourth insulating film 124 may include the active layer AL disposed on the upper surface and thus serve to planarize the upper surface for the base of the transistor T.

The fourth insulating film 124 may include an inorganic material. The inorganic material may include, for example, a silicon oxide film (SiOx) or a multilayer film in which inorganic films are laminated.

An active layer AL may be disposed on the fourth insulating film 124.

The active layer AL includes a channel area CA overlapping with the gate electrode G and first and second source drain regions SDA1 and SDA2 connected to first and second source drain electrodes SD1 and SD2.

The channel area CA is a region that overlaps the gate electrode G and where carriers move. The first source drain region SDA1 and the second source drain region SDA2 are regions excluding the channel area CA where the first source drain electrode SD1 and the second source drain electrode SD2 are respectively connected and electrons and holes are injected. The first source drain region SDA1 and the second source drain region SDA2 may be disposed on both sides of the channel area CA with the channel area CA interposed therebetween.

The first source drain region SDA1 and the second source drain region SDA2 include a conductive portion doped with impurities, or the like. The first source drain region SDA1 and the second source drain region SDA2 may include a region where a conductive region injected with impurities is mixed with a non-conductive region injected with no impurities.

The active layer AL includes an oxide semiconductor material including a first metal. The oxide semiconductor material may include an oxide of a first metal such as zinc (Zn), indium (In), gallium (Ga), tin (Sn), or titanium (Ti), or a combination of a first metal such as zinc (Zn), indium (In), gallium (Ga), tin (Sn), or titanium (Ti) and an oxide thereof.

More specifically, the oxide semiconductor material including a first metal constituting the active layer AL may include at least one of an IGZO (InGaZnO), IGO (InGaO), IGZTO (InGaZnSnO), GZTO (GaZnSnO), GZO (GaZnO), or GO (GaO)-based oxide semiconductor material. The active layer AL may have a single-film structure or a multilayer film structure including two or more oxide semiconductor materials.

The active layer AL including an oxide semiconductor material having a first metal is disposed on a substrate 111 and the active layer AL includes an oxide semiconductor material, so that the transistor improves the effect of blocking leakage current and thus reduces power consumption.

The gate insulating film 172 may be disposed on the active layer AL. Since the active layer AL is disposed on the third insulating film 123 in a pattern shape, the gate insulating film 172 is disposed to cover the top and side surfaces of the active layer A.

Since the gate insulating film 172 is disposed to cover the active layer AL containing an oxide semiconductor material, it may be formed of an inorganic material containing no hydrogen particles. For example, the gate insulating film 172 may include a silicon oxide layer (SiOx) or multiple layers in which inorganic layers are stacked.

The gate electrode G may be disposed on the gate insulating film 172. The gate electrode G turns on or turns off the second transistor DR (T) in response to a signal from the compensation circuit CC or the capacitor Cst shown in FIG. 2. The gate electrode G is insulated from the active layer AL through the gate insulating film 172, and is arranged such that at least part of the gate electrode G overlaps the active layer AL to form a channel area CA in the active layer AL.

The gate electrode G may contain a conductive metal material. Specifically, the conductive metal material includes at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), or titanium (Ti). The gate electrode G may have a multilayer structure including at least two conductive metal materials.

When current is applied to the gate electrode G, charges flow into the channel area CA of the active layer AL overlapping the gate electrode G. The transistor T according to the present disclosure has a second metal oxide insulating film 171 doped with the first metal of the active layer AL at the interface between the active layer AL and the gate insulating film 172 so as to allow charges to smoothly flow into the channel area CA of the active layer AL without being trapped.

The second metal oxide insulating film 171 doped with the first metal is disposed to cover the active layer AL so as to overlap with the channel area CA of the active layer AL at the interface between the active layer AL and the gate insulating film 172. The second metal oxide insulating film 171 doped with the first metal covers the entire upper surface of the active layer AL and contacts the upper surface and side surfaces of the active layer AL.

The second metal oxide insulating film 171 doped with the first metal may contact at least a part of the third insulating film 123 disposed below the active layer AL. The second metal oxide insulating film 171 doped with the first metal may contact the lower surface of the gate insulating film 172 and may contact the upper surface of the active layer AL.

The second metal oxide insulating film 171 doped with the first metal includes the same first metal as that included in the oxide semiconductor material of the active layer AL. The second metal oxide insulating film 171 doped with the first metal may include the first metal, a first metal-O (oxide) bonding, a second metal, a second metal-O bonding, or a first metal-second metal bonding.

Specifically, the first metal may be the same as the first metal of the active layer AL and may be Ga (gallium). When the second metal oxide insulating film 171 doped with the first metal functions as an additional gate insulating film, the additional gate insulating film may include Ga, Ga—O bonding, a second metal, a second metal-O bonding, and a Ga-second metal bonding.

The second metal of the second metal oxide insulating film 171 doped with the first metal may include one of group 3 (Sc, Y), group 4 (Ti, Zr, Hf), or group 5 (V, Nb, Ta) metals. When the first metal is Ga, the first metal-second metal bonding in the second metal oxide insulating film 171 may include, for example, any one of Ga—Ta, Ga—Zr, and Ga—Y.

When the surface of the channel area CA of the active layer AL comes into contact with the gate insulating film 172, the structure or properties of the gate insulating film 172 may be different from those of the active layer AL with which it comes into contact, and thus charges of the active layer AL may be trapped at the interface between the active layer AL and the gate insulating film 172 or at the lower surface of the gate insulating film 172. When the charge does not flow but is trapped between the active layer AL and the gate insulating film 172, it may affect the concentration or mobility of the charges, which may reduce the electrical stability of the transistor.

The transistor T applied to the display device 100 according to one embodiment of the present disclosure includes a second metal oxide insulating film 171 doped with a first metal between the active layer AL and the gate insulating film 172, and the second metal oxide insulating film 171 having smooth electron flow is in contact with the upper surface of the active layer AL. The second metal oxide insulating film 171 is doped with a first metal identical to the first metal of the active layer AL, so that it has a structure similar to the internal bonding structure of the active layer AL having the first metal.

In addition, the second metal oxide insulating film 171 has a bonding structure as an oxide insulating film and further has a bonding structure with the second metal, so that it has a structure similar to the gate insulating film 172 and at the same time, a portion where charges may be trapped is reduced compared to the gate insulating film 172.

The second metal oxide insulating film 171 doped with the first metal has a structure and properties similar to those of the lower active layer AL and the upper gate insulating film 172 at the interface between the active layer AL and the gate insulating film 172, so that charges flowing into the active layer AL or the surface of the active layer AL can flow smoothly through the second metal oxide insulating film 171 without being trapped between the overlapping gate insulating films 172. In addition, the second metal oxide insulating film 171 doped with the first metal is disposed between the active layer AL and the gate insulating film 172, and has a lower interface trap density than the upper gate insulating film 172, so that charges can flow smoothly without being trapped from the active layer AL forming the interface and thus reducing occurrence of afterimage or the like.

The transistor T of the display device 100 according to one embodiment of the present disclosure has a second metal oxide insulating film 171 doped with a first metal disposed at the interface between an active layer AL having a first metal and a gate insulating film 172, so that charges flowing through the active layer AL or the surface of the active layer AL are not trapped, thereby maintaining the concentration and mobility of charges uniformly, maintaining the brightness of the transistor T uniformly, improving stability and reliability, and minimizing the occurrence of afterimages in the display device 100.

In addition, the transistor according to one embodiment of the present disclosure includes a second metal oxide insulating film 171 doped with the first metal disposed at the interface between the active layer AL having the first metal and the gate insulating film 172, thereby preventing current or charge from being trapped, maintaining the level of the on-current of the transistor T uniformly, preventing an increase in the level of the off-current, reducing the occurrence of leakage current, and providing high-speed operation of the transistor T.

The second metal oxide insulating film 171 doped with the first metal may have electrical or chemical properties as an oxide insulating film and function as a general gate insulating film. That is, the second metal oxide insulating film 171 doped with the first metal may function as an additional gate insulating film under the gate insulating film 172.

The second metal oxide insulating film 171 doped with the first metal may further improve the stability and reliability of the transistor T by controlling the density distribution of bonding structures within the second metal oxide insulating film 171. The density distribution of bonding structures within the second metal oxide insulating film 171 doped with the first metal may be applied according to the embodiment described with reference to FIG. 4.

The planarization film 130 may be disposed on the transistor T.

The planarization film 130 may be disposed on the transistor T to protect the transistor T and to reduce the step caused by the transistor T. The planarization film 130 may be disposed on an insulating film 120 to provide a flat surface.

In order to prevent generation of parasitic capacitance between the transistor T, the wires (not shown), and the light emitting element 145, the planarization film 130 may be disposed between the structures or components.

The planarization film 130 may be disposed on the insulating film 120 of the planarization film 130 to provide a flat surface.

The planarization film 130 may include an organic material. The organic material includes at least one of an acryl resin, a phenolic resin, a polyimide resin, an unsaturated polyester resin, a polyamide resin, benzocyclobutene, a polyphenylene resin, or a polyphenylene sulfide resin.

The planarization film 130 may be disposed as a composite laminate including an inorganic insulating material film and an organic insulating material film. In addition to the insulating film 120 described above, various organic or inorganic materials may be disposed between the substrate 111 and the planarization film 130.

The bank 135 is a pixel-defining layer to expose the first electrode E1 of each sub-pixel SP (see FIGS. 1 and 2). The bank 135 may include an opaque material (e.g., black) to prevent light interference between adjacent sub-pixels SP. In this case, the bank 135 may include a light-blocking material formed of at least one of a color pigment, organic black, or carbon.

The light emitting element 145 is disposed on the planarization film 130 in the display area AA.

The light emitting element 145 includes a first electrode E1, a light emitting layer EL, and a second electrode E2. The light emitting element 145 may be electrically connected to the second transistor DR (T) through the planarization film 130. The first electrode E1 of the light emitting element 145 and the second source drain electrode SD2 of the transistor T are electrically connected to each other. The transistor T may function as a driving transistor.

The first electrode E1 may function as an anode. The first electrode E1 may pass through the planarization film 130 and may be connected to the transistor T. The first electrode E1 may be directly connected to the transistor T or may be connected via an intermediate medium (e.g., another transistor).

The first electrode E1 may include a metal material with high reflectivity. For example, the first electrode E1 has a multilayer structure such as a laminate structure (Ti/Al/Ti) of aluminum (Al) and titanium (Ti), a laminate structure (ITO/Al/ITO) of aluminum (Al) and ITO, an APC (Ag/Pd/Cu) alloy, a laminated structure (ITO/APC/ITO) of an APC alloy and ITO, or a laminated structure (Ag/MoTI) of silver (Ag) and molybdenum/titanium alloy, or a single layer structure containing any one selected from silver (Ag), aluminum (Al), molybdenum (Mo), gold (Au), magnesium (Mg), calcium (Ca), or barium (Ba), or an alloy containing two or more thereof. The first electrode E1 may be called a “reflective electrode”.

A light emitting layer EL is provided on the first electrode EL. The light emitting layer EL may include a hole injection layer, a hole transport layer, an organic light emitting layer, an electron transport layer, and an electron injection layer.

When a voltage is applied to the first electrode E1 and the second electrode E2, holes are transferred to the organic light emitting layer through the hole injection layer and the hole transport layer, electrons are transferred to the organic light emitting layer through the electron injection layer and the electron transport layer, the holes recombine with the electrons in the organic light emitting layer to form excitons, and the energy of excitons drops from the excited state to the ground state, thus causing light emission.

The light emitting layer EL may include a red light emitting layer that emits red light, a green light emitting layer that emits green light, and a blue light emitting layer that emits blue light. The red light emitting layer, the green light emitting layer, and the blue light emitting layer may be arranged for each sub-pixel SP on the first electrode E1.

The red light emitting layer may be patterned in the red sub-pixel, the green light emitting layer may be patterned in the green sub-pixel, and the blue light emitting layer may be patterned in the blue sub-pixel, but these configurations are not limited thereto. At least two organic light emitting layers among the red light emitting layer, the green light emitting layer, and the blue light emitting layer may be stacked and disposed in one sub-pixel SP.

The light emitting layer EL may be a white light emitting layer that emits white light. In this case, the light emitting layer EL may be a common layer in which one or more non-patterned layers are commonly disposed in the sub-pixels SP.

As previously described, the light emitting layer EL may be arranged in a tandem structure of two or more stacks (STACK). In this case, each light emitting device 145 may include a charge generation layer disposed between stacks. The charge generation layer may be a common layer disposed on the entire surface of the display area AA.

A second electrode E2 is provided on the light emitting layer EL. The second electrode E2 may function as a cathode.

The second electrode E2 may be disposed not only in the light emitting area of the sub-pixel SP but also in the entire region of the display area AA, but is not limited thereto. The second electrode E2 may be a common layer that is commonly disposed in the sub-pixels SP and applies the same voltage thereto. For this purpose, the second electrode E2 may be arranged to extend from the display area AA to a part of the non-display area NA.

The second electrode E2 may be a light transmitting electrode. The second electrode E2 may include a transparent metal material (TCO) such as ITO or IZO that can transmit light, or include a semi-transmissive conductive material such as magnesium (Mg), silver (Ag), or an alloy of magnesium (Mg) and silver (Ag). When the second electrode E2 is formed of a translucent metal material, light output efficiency can be increased due to microcavities.

As an example of the light emitting element 145, a front light emitting type has been described above, but the light emitting element 145 of the present disclosure is not limited thereto. The light emitting element 145 may be a bottom-emitting type in which light emitted from the light emitting layer EL is emitted toward the substrate 111. In this case, the first electrode E1 may be formed of a transparent or translucent electrode material, and the second electrode E2 may be formed of a reflective electrode material.

An encapsulation layer 150 is disposed on the light emitting element 145. The encapsulation layer 150 may cover the display area AA and the non-display area NA to prevent oxygen or moisture from penetrating into the light emitting element 145. If necessary, other layers such as a capping layer may be interposed between the encapsulation layer 150 and the second electrode E2.

The encapsulation layer 150 may include a plurality of layers. The encapsulation layer 150 may have a structure in which inorganic films containing an inorganic insulating material and organic films containing an organic insulating material are alternately stacked. For example, the inorganic insulating material may include one or more materials such as silicon oxide, silicon nitride, and/or silicon oxynitride.

The organic insulating material may include at least one selected from the group consisting of polyethylene terephthalate, polyethylene naphthalate, polycarbonate, polyimide, polyethylene sulfonate, polyoxymethylene, polyarylate, and hexamethyldisiloxane.

According to an embodiment of the present disclosure, a display device 100 includes a second metal oxide insulating film 171 doped with a first metal disposed at the interface between an active layer AL having a first metal and a gate insulating film 172, thereby reducing the thickness of an active layer AL, increasing a threshold voltage Vth based on the reduced channel thickness of the active layer AL, reducing the size of a transistor T, and realizing a high-resolution display device 100. In addition, the threshold voltage Vth of the display device 100 may be lowered as the size of the transistor T is reduced, but the present disclosure enables an increase in the threshold voltage Vth by reducing the thickness of the channel area CA of the active layer AL, thereby preventing the threshold voltage Vth from being lowered and providing the stability and reliability of the display device 100.

The display device 100 according to the present disclosure secures the stability and reliability of the display device 100 and reduces the defect rate, thereby reducing the production energy for producing the display device, reducing the generation of greenhouse gases that may be generated due to the manufacturing process, and realizing ESG (environmental/social/governance) goals.

In addition, the transistor and the display device 100 according to the present disclosure improve reliability, thereby reducing the energy required to produce the display device 100, and reducing the production of harmful substances or the use of regulated substances, thus being advantageous for recycling and obtaining an eco-friendly display device 100.

As apparent from the foregoing, the transistor and the display device including the same according to the present disclosure can maintain uniform brightness by minimizing defects at the interface between the active layer and the gate insulating film.

The transistor and display device according to the present disclosure can maintain uniform levels of on current, prevent an increase in the level of off current, reduce the occurrence of leakage current, and provide high-speed operation by minimizing defects at the interface between the active layer and the gate insulating film.

The transistor and display device according to the present disclosure can increase threshold voltage and reduce the size of the transistor by minimizing defects at the interface between the active layer and the gate insulating film.

The transistor and display device according to the present disclosure can improve driving stability and reliability by minimizing defects at the interface between the active layer and the gate insulating film.

The transistor and display device according to the present disclosure can minimize the occurrence of afterimages by minimizing defects at the interface between the active layer and the gate insulating film.

The transistor and display device according to the present disclosure can reduce the amount of materials used in the process by reducing the defect rate, thereby reducing carbon emissions.

It will be apparent to those skilled in the art that various modifications and variations can be made in the disclosure without departing from the spirit or scope of the disclosure. Thus, it is intended that the disclosure cover such modifications and variations thereof, provided they fall within the scope of the appended claims and their equivalents.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A transistor comprising:
an active layer on a substrate, the active layer including an oxide semiconductor material having a first metal;
a gate insulating film on the active layer;
a gate electrode at least partially overlapping the active layer on the gate insulating film;
a first source-drain electrode and a second source-drain electrode respectively coupled to a first source-drain region and a second source-drain region of the active layer, while being insulated from the gate electrode; and
a second metal oxide insulating film doped with the first metal, the second metal oxide insulating film being disposed between the gate insulating film and the active layer.

2. The transistor according to claim 1, wherein the second metal oxide insulating film doped with the first metal is an additional gate insulating film.

3. The transistor according to claim 2, wherein the additional gate insulating film comprises Ga, Ga—O bonding, a second metal, a second metal-O bonding, and a Ga-second metal bonding, and
wherein the second metal is a metal different from Ga.

4. The transistor according to claim 1, wherein the second metal oxide insulating film doped with the first metal includes a first metal, a first metal-O bonding, a second metal, a second metal-O bonding, and a first metal-second metal bonding.

5. The transistor according to claim 4, wherein a density of the first metal in the second metal oxide insulating film doped with the first metal increases with a decreasing distance from the active layer.

6. The transistor according to claim 4, wherein the density of the second metal or the density of the second metal-O bonding in the second metal oxide insulating film doped with the first metal increases with a decreasing distance from the gate insulating film.

7. The transistor according to claim 4, wherein the density of the first metal-O bonding in the second metal oxide insulating film doped with the first metal increases with a decreasing distance from the active layer.

8. The transistor according to claim 1, wherein the second metal oxide insulating film doped with the first metal is in contact with a lower surface of the gate insulating film and is in contact with an upper surface of the active layer.

9. The transistor according to claim 1, wherein the oxide semiconductor material comprises at least one of an IGZO (InGaZnO)-based oxide semiconductor material, an IGO (InGaO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, or a GO (GaO)-based oxide semiconductor material.

10. The transistor according to claim 1, wherein the first metal comprises Ga.

11. The transistor according to claim 1, wherein the second metal comprises one of group 3 (Sc, Y), group 4 (Ti, Zr, Hf), and group 5 (V, Nb, Ta).

12. The transistor according to claim 1, wherein the second metal oxide insulating film doped with the first metal is disposed in a pattern corresponding to an area where the gate electrode and the active layer overlap.

13. The transistor according to claim 1, wherein the second metal oxide insulating film doped with the first metal is disposed in an area where a channel area of the active layer overlaps, and the gate insulating film is disposed in an area where the entire area of the active layer overlaps.

14. The transistor according to claim 1, wherein the second metal oxide insulating film doped with the first metal comprises:
a first additional gate insulating film on the active layer;
a second additional gate insulating film on the first additional gate insulating film; and
a third additional gate insulating film on the second additional gate insulating film,
wherein the first additional gate insulating film is in contact with an upper surface of the active layer, and the third additional gate insulating film is in contact with a lower surface of the gate insulating film.

15. A display device comprising:
a substrate;
a transistor on the substrate;
a planarization film on the transistor;
a light emitting element on the planarization film; and
an encapsulation layer on the light emitting element,
wherein the transistor comprises:
an active layer on a substrate, the active layer including an oxide semiconductor material having a first metal;
a gate insulating film on the active layer;
a gate electrode at least partially overlapping the active layer on the gate insulating film;
a first source-drain electrode and a second source-drain electrode respectively coupled to a first source-drain region and a second source-drain region of the active layer, while being insulated from the gate electrode; and
a second metal oxide insulating film doped with the first metal, the second metal oxide insulating film being disposed between the gate insulating film and the active layer.

16. The display device according to claim 15, wherein the transistor is a driving transistor.

17. The display device according to claim 15, wherein the second metal oxide insulating film doped with the first metal is an additional gate insulating film.

18. The display device according to claim 17, wherein the additional gate insulating film comprises Ga, Ga—O bonding, a second metal, a second metal-O bonding, and a Ga-second metal bonding, and
wherein the second metal is a metal different from Ga.

19. The display device according to claim 15, wherein the second metal oxide insulating film doped with the first metal includes a first metal, a first metal-O bonding, a second metal, a second metal-O bonding, and a first metal-second metal bonding.

20. The display device according to claim 15, wherein the second metal oxide insulating film doped with the first metal is in contact with a lower surface of the gate insulating film and is in contact with an upper surface of the active layer.
